(19) United States
(12) Patent Application Publication
(10) Pub. No.: US 2009/0085202 A1
(43) Pub. Date: Apr. 2, 2009

(54) Methods and Apparatus for Assembling Integrated Circuit Device Utilizing a Thin Si Interposer

(76) Inventors: Bing Dang, Chappaqua, NY (US); Mario J. Interrante, New Paltz, NY (US); John Ulrich Knickerbocker, Monroe, NY (US); Edmund Juris Sprogis, Underhill, VT (US); Son K. Tran, Endwell, NY (US)

Correspondence Address: RYAN, MASON & LEWIS, LLP, 90 FOREST AVENUE, LOCUST VALLEY, NY, 11560, US

(21) Appl. No.: 11/862,609

(22) Filed: Sep. 27, 2007

(51) Int. Cl. H01L 23/48; H01L 21/44

(52) U.S. Cl. 257/737; 438/613; 257/E23.01; 257/E21.476

(57) ABSTRACT

Methods of assembling an integrated circuit are provided. An interposer supported by an integrated handler is solder bumped onto one or more bond pads on a substrate. The integrated handler is removed from the interposer. A side of the interposer opposite that of the substrate is solder bumped to one or more bond pads on a chip.

### FIELD OF THE INVENTION

The present invention relates generally to the field of integrated circuits and, more particularly, to assembly operations performed on an integrated circuit for packaging.

### BACKGROUND OF THE INVENTION

As the complexity of integrated circuit technology increases, requiring an increased number of linked transistors, the integrated circuitry dimensions are shrinking. Thus, a specific challenge in the semiconductor industry is to develop improved methods for electrically connecting and packaging circuit devices. Such improvements may include the construction of transistors which occupy less surface area on the silicon chip/die for the semiconductor industry.

The decreasing size of integrated circuit (IC) packages and increasing size and level of circuit integration in the IC packages is particularly true in the case of system-on-a-chip (SoC) devices. Most, if not all, of an electronic appliance of SoC devices is integrated onto a single integrated circuit (IC) die. However, as the number and complexity of devices increase, it becomes more and more important to pack as many IC dies as possible onto circuit board. Meanwhile, miniaturization of systems is desired for most electronic applications. In order to further these objectives, manufactures place IC dies as close together as possible on a substrate to increase IC die density and reduce the interconnection distance between IC dies. The ultimate solution is to stack IC dies vertically in order to minimize the signal delay. Conventional chip stacking involves wire bonding, which has relatively low interconnection density and lager electrical parasitics. Die stacking with area array interconnection can maximize the interconnection density and minimize interconnection distance, thus improve the overall performance a system of the integrated circuit dies.

Stacking of multiple levels of integrated circuit dies with area array interconnects requires careful design of bonding metallurgy hierarchy and assembly processes. In addition, the stacked integrated circuit dies are usually thinned significantly to ensure small total thickness for the packages. Therefore, novel assembly method and apparatus are needed to facilitate the bumping and stacking of the fragile thin Si dies.

### SUMMARY OF THE INVENTION

The present invention in an illustrative embodiment provides techniques for assembling integrated circuit devices using a thin silicon (Si) interposer.

In accordance with one aspect of the invention, a method of assembling an integrated circuit is provided. An interposer supported by an integrated handler is solder bumped onto one or more bond pads on a substrate. The integrated handler is removed from the interposer. A side of the interposer opposite that of the substrate is solder bumped to one or more bond pads on a chip.

In accordance with another aspect of the invention, a method of assembling an integrated circuit is provided. An interposer supported by an integrated handler is solder bumped to a temporary chip attach structure. The integrated handler is removed from the interposer. A side of the interposer opposite that of the temporary chip attach structure is solder bumped to one or more bond pads of a chip to form an interposer-chip stack on the temporary chip attach structure. The interposer-chip stack is removed from the temporary chip attach structure. The interposer-chip stack is solder bumped to one or more bonding pads on a substrate.

Additional embodiments of the present invention may include the steps of cleaning the interposer after the handler is removed and reballing the solder bumps after the interposer-chip stack is removed from the temporary chip attach structure.

In accordance with another aspect of the invention, an integrated circuit is provided. The integrated circuit comprises a die having one or more bond pads. One or more solder bumps are connected to the one or more bond pads of the die. An interposer is connected via the one or more solder bumps to the one or more bond pads of the die.

Further embodiments of the present invention may comprise underfill between the die and interposer surrounding the one or more solder bumps. These embodiments may also comprise one or more additional solder bumps on a side of the interposer opposite that of the die, and a substrate having a one or more bond pads connected to the one or more additional solder bumps on a side of the interposer opposite that of the die.

These and other objects, features, and advantages of the present invention will become apparent from the following detailed description of the illustrative embodiments thereof, which is to be read in connection with the accompanying drawings.

### BRIEF DESCRIPTION OF THE DRAWINGS

FIG. 1 is a diagram illustrating a bumping and assembly process of a Si carrier to a ceramic substrate, according to an embodiment of the present invention;

FIG. 2 is a diagram illustrating a bumping and assembly process of a Si carrier to a ceramic substrate using a TCA, according to an embodiment of the present invention;

FIG. 3 is a diagram illustrating substrate first bumping and assembly process of a Si carrier, according to an embodiment of the present invention;

FIG. 4 is a diagram illustrating a bumping and assembly process of a Si carrier to an organic substrate using a TCA, according to an embodiment of the present invention;

FIG. 5 is a diagram illustrating a bumping and assembly process of an Si carrier that enables fine pitch capability for conventional TCA structures, according to an embodiment of the present invention;

FIG. 6 is a flow diagram illustrating a bumping and assembly methodology for a Si carrier, according to an embodiment of the present invention;

FIG. 7 is a flow diagram illustrating a bumping and assembly methodology for an Si carrier using a TCA, according to an embodiment of the present invention; and

FIG. 8 is a block diagram illustrating an example of a bonding system in which a bumping and assembly technique of the invention may be implemented.

### DETAILED DESCRIPTION

As will be described in detail below, the present invention in the illustrative embodiment achieves assembly of Si carrier to chips and substrate to permit effective assembly, test and high yield.

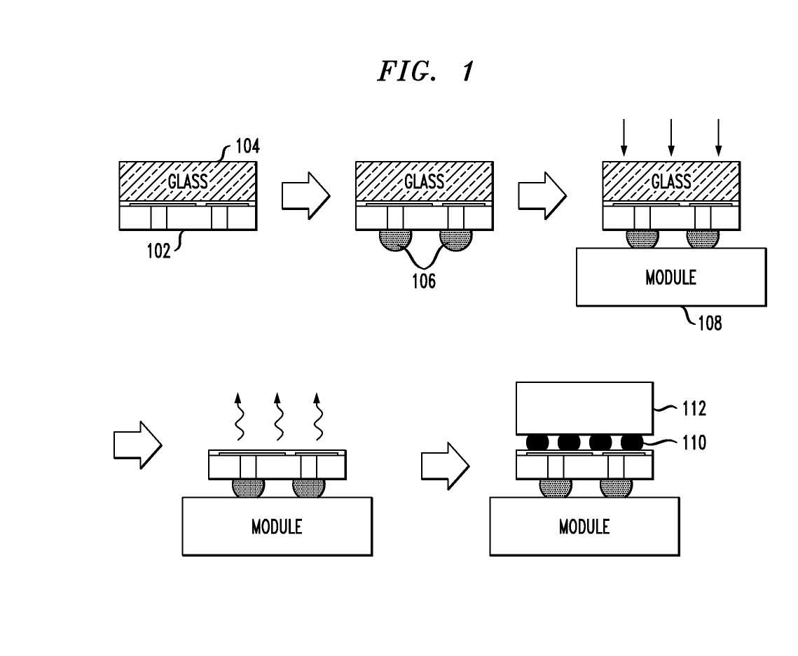

Referring initially to FIG. 1, a diagram illustrates a bumping and assembly process of a Si carrier for ceramic substrates, according to an embodiment of the present invention. An interposer 102 with an integrated handler 104 is provided. Interposer 102 is preferably a Si interposer. Interposer 102 has a high bandwidth but is very fragile and thin (20-100 microns) and thus requires a handler. Handler 104 may be a glass handler as shown in FIG. 1. Handler 104 allows for safe handling and assembly of thin Si interposer 102. Solder bumps 106 are formed on an underside of Si interposer 102, for attachment to bond pads of a module 108, or Si carrier. Handler 104 holds thin Si interposer 102 flat to assist the solder bumps to contact bond pads on module 108. Integrated handler 104 is removed through a laser, UV, thermal or vacuum release leaving Si interposer 102 to be supported by module 108. For example, a porous glass handler may be dissolved through a chemical reaction. The surface of Si interposer is cleaned by ashing or reactive ion etch (RIE), before additional solder bumps 110 are formed on a top surface of Si interposer 102 for connection to an integrated circuit die or chip 112. 97/3 PbSn or Pb-free SnCu solder bumps may be provided for both the chip and interposer. Additionally, 97/3 PbSn solder bumps may be provided for the chip, while 90/10 or 85/15 PbSn solder bumps may be provided for the interposer. Finally 97/3 PbSn solder bumps may be provided for the chip, while 63/37 PbSn solder bumps may be provided for the interposer.

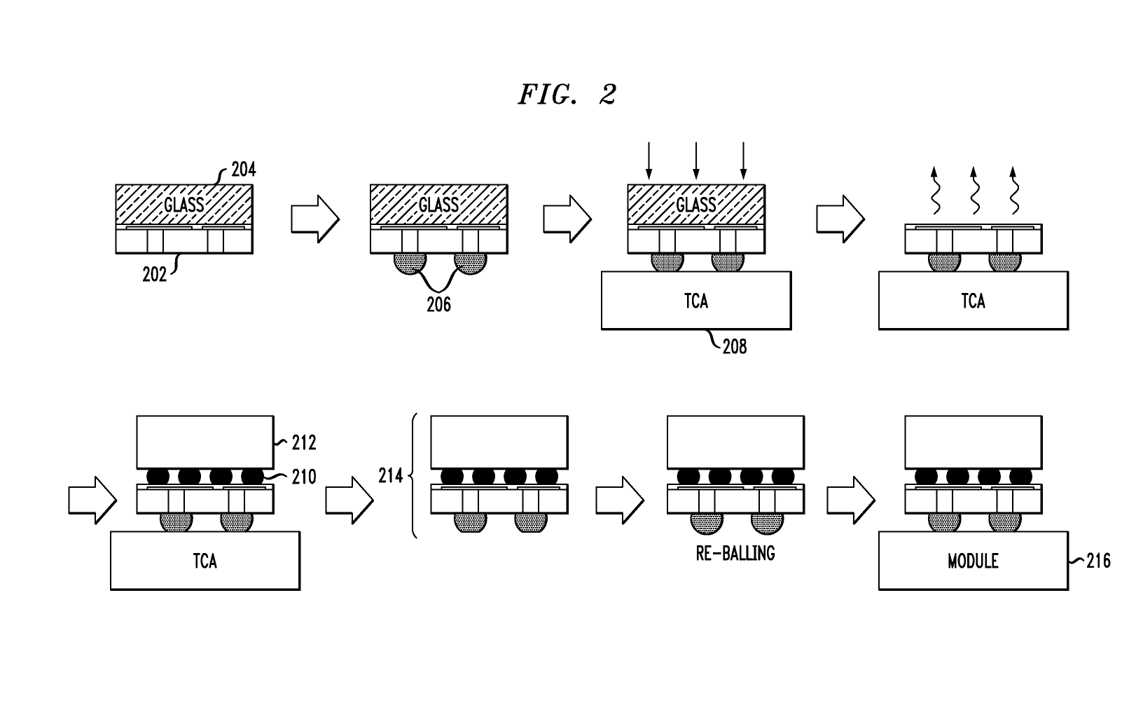

Referring now to FIG. 2, a diagram illustrates a bumping and assembly process of a Si carrier to a ceramic substrate using a temporary chip attach (TCA) structure, according to an embodiment of the present invention. A Si interposer 202 with an integrated handler 204 is provided. Solder bumps 206 are formed on an underside of Si interposer 202 for attachment to a TCA structure 208. Handler 204 is removed through a laser, UV, thermal or mechanical process, leaving Si interposer 202 to be supported by TCA structure 208. The surface of Si interposer 202 is cleaned by ashing or RWE, before additional solder bumps 210 are formed on a top surface of Si interposer 202 for connection to an integrated circuit die or chip 212. TCA structure 208 is removed from stacked interposer-chip assembly 214, and solder bumps 206 are re-balled for connection to bond pads of a module 216. 97/3 PbSn or Pb-free SnCu solder bumps may be provided for both the chip and interposer. Additionally, 97/3 PbSn solder bumps may be provided for the chip, while 90/10 or 85/15 PbSn solder bumps may be provided for the interposer. Finally 97/3 PbSn solder bumps may be provided for the chip, while 63/37 PbSn solder bumps may be provided for the interposer.

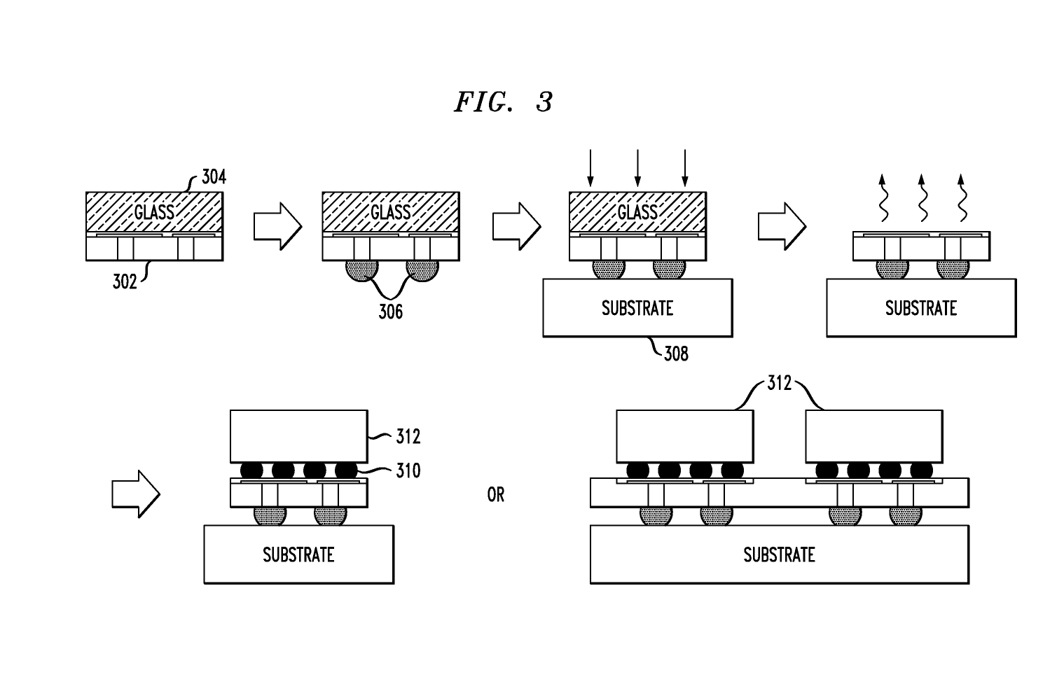

Referring now to FIG. 3, a diagram illustrates substrate first bumping and assembly process of a Si carrier, according to an embodiment of the present invention. A Si interposer 302 with handler 304 is provided. Solder bumps 306 are formed on an underside of Si interposer 302 for attachment to a substrate 308. Handler 304 is removed through laser ablation, leaving Si interposer 302 to be supported by substrate 308. The surface of Si interposer 302 is cleaned by ashing before additional solder bumps 310 are formed on a top surface of Si interposer 302 for connection to bond pads of an integrated circuit die or chip 312. Si interposer 302 may also provide connections for multiple chips 312. 97/3 PbSn solder bumps may be provided for the chip and 90/10 or 85/15 PbSn solder bumps may be provided for the interposer.

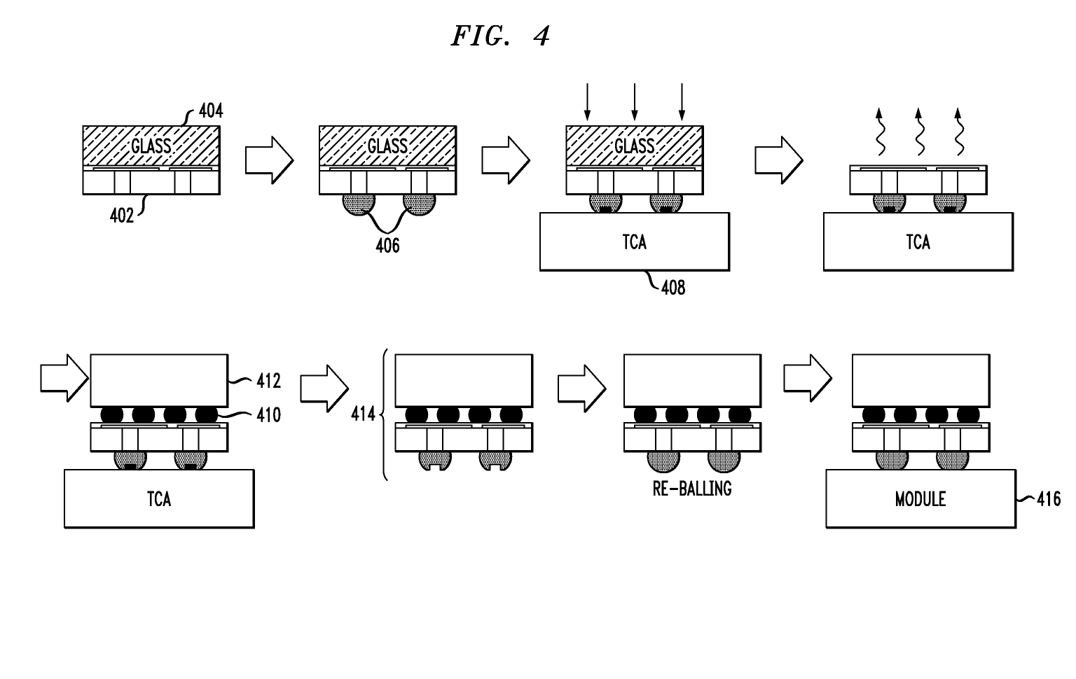

Referring now to FIG. 4, a diagram illustrates a bumping and assembly process of a Si carrier to an organic substrate using a TCA structure, according to an embodiment of the present invention. A Si interposer 402 with handler 404 is provided. Solder bumps 406 are formed on an underside of Si interposer 402 for attachment to a TCA structure 408. Handler 404 is removed through a laser, UV, thermal or mechanical process, leaving Si interposer 402 to be supported by TCA structure 408. The surface of Si interposer 402 is cleaned by ashing before additional solder bumps 410 are formed on a top surface of Si interposer for connection to bond pads of an integrated circuit die or chip 412. TCA structure 408 is removed from stacked interposer-chip assembly 414, and solder bumps 406 are re-balled for connection to bond pads of a module 416. 97/3 PbSn solder bumps may be provided for the chip and interposer and 63/37 PbSn solder bumps may be provided for the organic substrate. The solder bumps may be Pb-free SnCu solder bumps for the chip and interposer. Further, 97/3 PbSn solder bumps may be provided for the chip, 90/10 or 85/15 PbSn solder bumps may be provided for the interposer, and 63/37 PbSn solder bumps may be provided for the organic substrate. Finally, 97/3 PbSn solder bumps may be provided fro the chip and 63/37 PbSn solder bumps may be provided for the interposer and the substrate.

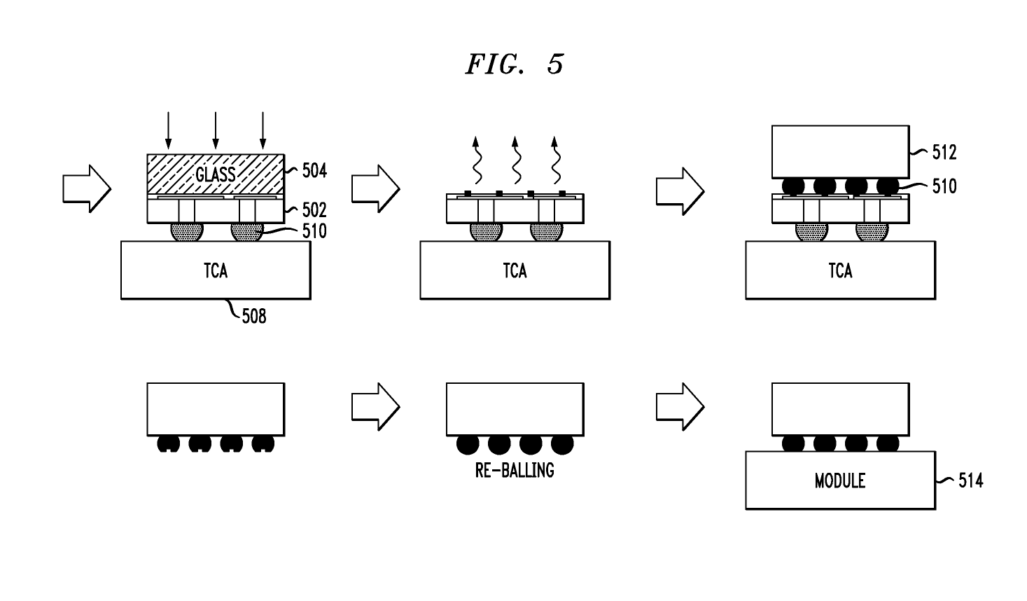

Referring now to FIG. 5, a diagram illustrates a bumping and assembly process of a Si carrier that enables fine pitch capability for conventional TCA structures, according to an embodiment of the present invention. A Si interposer 502 having a handler 504 is connected via solder bumps 506 to a TCA structure 508. Handler 504 is removed through a laser, UV, thermal or mechanical process, leaving Si interposer 502 to be supported by TCA structure 508. The surface of Si interposer 502 is cleaned by ashing before additional solder bumps 510 are formed on a top surface of Si interposer for connection to bond pads of an integrated circuit die or chip 512. Si interposer 502 and TCA structure 508 are removed from chip 512 and solder bumps 510 are re-balled for connection of chip 512 to a module 514. 97/3 PbSn or Pb-free SnCu solder bumps may be provided for both the chip and interposer. Additionally, 97/3 PbSn solder bumps may be provided for the chip, while 90/10 or 85/15 PbSn solder bumps may be provided for the interposer. Finally 97/3 PbSn solder bumps may be provided for the chip, while 63/37 PbSn solder bumps may be provided for the interposer.

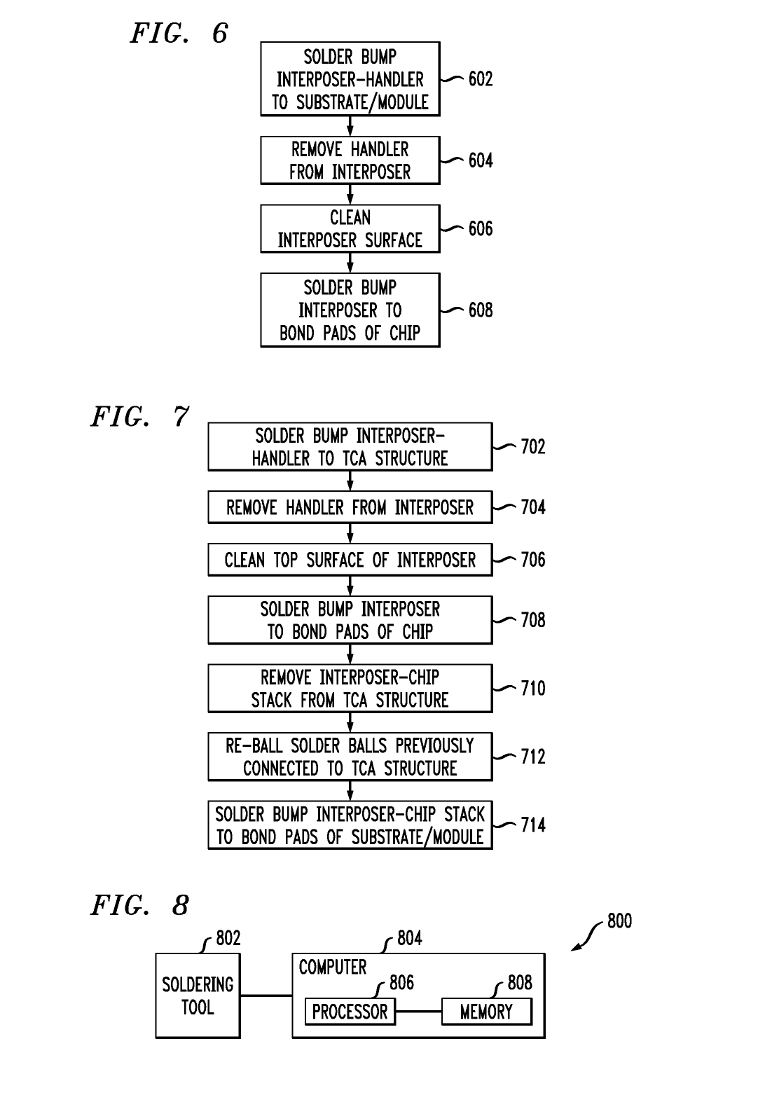

Referring now to FIG. 6, a flow diagram illustrates a bumping and assembly methodology for a Si carrier, according to an embodiment of the present invention. The methodology begins in block 602 in which an interposer and integrated handler are solder bumped to bond pads of a substrate or module. In block 604, the integrated handler is removed from the interposer. In block 606, the surface of the interposer is cleaned. Finally, in block 608, the top surface of the interposer is solder bumped to bond pads of a chip, terminating the methodology.

Referring now to FIG. 7, a flow diagram illustrates a bumping and assembly methodology for a Si carrier using a TCA, according to an embodiment of the present invention. The methodology begins in block 702 in which an interposer and integrated handler are solder bumped to a TCA structure. In block 704, the integrated handler is removed from the interposer. In block 706, the top surface of the interposer is cleaned. In block 708, the top surface of the interposer is solder bumped to bond pads of a chip. In block 710, the interposer-chip stack is removed from the TCA structure. In block 712, solder bumps that previously connected the interposer-chip stack to the TCA structure are re-balled. Finally, in block 714, the interposer-chip stack is solder bumped to bond pads of a substrate or module.

Referring now to FIG. 8, a block diagram illustrates an example of bonding system 800 in which a bumping and assembly technique of the invention may be implemented. As illustrated, the system 800 comprises a soldering tool 802 coupled to a computer 804 which may comprise a processor 806 and a memory 808. One or more of the steps shown in FIG. 1-7 may be performed at least in part utilizing software executed by processor 806 and stored in memory 808.

Additional embodiments of the present invention may incorporate various numbers and combinations of transistor dies, tuning capacitors, leads, or other circuit elements, arranged in various configurations within a given integrated circuit.

Therefore, although illustrative embodiments of the present invention have been described herein with reference to the accompanying drawings, it is to be understood that the invention is not limited to those precise embodiments, and that various other changes and modification may be made by one skilled in the art without departing from the scope or spirit of the invention.

What is claimed is:

1. A method of assembling an integrated circuit comprising the steps of:
solder bumping an interposer supported by an integrated handler to one or more bond pads on a substrate;
removing the integrated handler from the interposer; and
solder bumping a side of the interposer opposite that of the substrate to one or more bond pads on a chip.

2. The method of claim 1, wherein the interposer comprises a silicon interposer.

3. The method of claim 1, wherein the integrated handler comprises a glass handler.

4. The method of claim 1, wherein the step of removing the integrated handler comprises the step of lifting the integrated handler with at least one of a laser, ultra-violet, thermal, chemical and vacuum process.

5. The method of claim 1, further comprising the step of cleaning the interposer after the integrated handler is removed.

6. The method of claim 5, wherein in the step of cleaning the interposer is carried out via at least one of an ashing and reactive ion etch technique.

7. A method of assembling an integrated circuit comprising the steps of:
solder bumping a interposer supported by an integrated handler to a temporary chip attach structure;
removing the integrated handler from the interposer;
solder bumping a side of the interposer opposite that of the temporary chip attach structure to one or more bond pads of a chip to form an interposer-chip stack on the temporary chip attach structure;
removing the interposer-chip stack from the temporary chip attach structure; and
solder bumping the interposer-chip stack to one or more bonding pads on a substrate.

8. The method of claim 7, wherein the interposer comprises a silicon interposer.

9. The method of claim 7, wherein the integrated handler comprises a glass handler.

10. The method of claim 7, wherein the step of removing the integrated handler comprises the step of lifting the integrated handler with at least one of a laser, ultra-violet, thermal, chemical and vacuum process.

11. The method of claim 7, further comprising the step of cleaning the interposer after the integrated handler is removed.

12. The method of claim 11, wherein in the step of cleaning the interposer, the interposer is cleaned via at least one of an ashing and reactive ion etch technique.

13. The method of claim 7, further comprising the step of under filling a space between the chip and interposer.

14. The method of claim 7, further comprising the step of re-balling one or more solder bumps after the interposer-chip stack is removed from the temporary chip attach structure.

15. An integrated circuit device comprising:
a die having one or more bond pads;
one or more solder bumps connected to the one or more bond pads of the die; and
a interposer connected via the one or more solder bumps to the one or more bond pads of the die.

16. The integrated circuit device of claim 15, wherein the interposer comprises a silicon interposer.

17. The integrated circuit device of claim 15, further comprising an underfill between the die and interposer surrounding the one or more solder bumps.

18. The integrated circuit device of claim 15, further comprising one or more additional solder bumps on a side of the interposer opposite that of the die.

19. The integrated circuit device of claim 18, further comprising a substrate having a one or more bond pads connected to the one or more additional solder bumps on a side of the interposer opposite that of the die.

20. The integrated circuit device of claim 19, wherein at least one of:
the one or more solder bumps and the one or more additional solder bumps comprise 97/3 PbSn solder bumps;
the one or more solder bumps and the one or more additional solder bumps comprise Pb-free SnCu solder bumps;
the one or more additional solder bumps comprise 97/3 PbSn solder bumps and the one or more solder bumps comprise at least one of 90/10 and 85/15 PbSn solder bumps; or
the one or more additional solder bumps comprise 97/3 PbSn solder bumps and the one or more solder bumps comprise 63/37 PbSn solder bumps.
